(19) United States
(12) Patent Application Publication
(10) Pub. No.: US 2010/0225342 A1
(43) Pub. Date: Sep. 9, 2010

(54) PROBE CARD AND MICROSTRUCTURE INSPECTING APPARATUS

(75) Inventors: Masato Hayashi, Hyogo (JP); Kyota Sato, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/294,481

(22) PCT Filed: Sep. 28, 2007
(86) PCT No.: PCT/JP2007/069003

§ 371 Date: Sep. 25, 2008

(30) Foreign Application Priority Data
Sep. 29, 2006 (JP) 2006-268431

(51) Int. Cl. G01R 31/02

(52) U.S. Cl. 324/754

(57) ABSTRACT

A probe card 4 connected with an evaluation unit for evaluating a characteristic of a microstructure formed on a wafer 8 by outputting a test sound wave to a movable section 16a of the microstructure, includes: a probe 4a, which is electrically connected with an inspection electrode of the microstructure formed on the wafer 8, for detecting, in a test, an electric variation based on a movement of the movable section 16a formed on the wafer 8; and at least one of a sound absorber 11, a blocking portion 18 and a horn 19 for suppressing a reflection or an interference of the test sound wave. A diffusion portion may be provided instead of or additional to the sound absorber 11. Further, a microstructure inspecting apparatus includes the probe card 4 having the sound absorber 11, the blocking portion 18 or the horn 19.

### TECHNICAL FIELD

The present invention relates to a probe card and an inspecting apparatus for inspecting a microstructure such as MEMS (Micro Electro Mechanical Systems).

### BACKGROUND ART

Recently, MEMS devices, which integrate various mechanical, electronic, optical and chemical functions by using a microfabrication technology or the like, are attracting attention. As examples of MEMS technology that have been in practical use, there are sensors used in an automobile or a medical field, and the MEMS devices are installed in microsensors such as an acceleration sensor, a pressure sensor, an air flow sensor or the like. Further, an application of the MEMS technology to an inkjet printer head has enabled an increase of the number of nozzles for jetting ink and an improvement of ink jetting accuracy, which in turn allows an enhancement of printing quality and speed. Further, a micro mirror array or the like used in a reflective type projector is also known as a general MEMS device.

It is expected that development of various sensors or actuators using the MEMS technology will expand application range of the MEMS devices to an optical communication/mobile device, a peripheral device of a calculator, a bio-analysis system, a mobile power source, and so forth.

Meanwhile, with the development of the MEMS devices, a method for properly inspecting the MEMS devices is also getting important especially because the MEMS devices are formed of microstructures. Conventionally, evaluation on device characteristics of the MEMS devices has been performed after packaging the MEMS devices, by way of rotating or vibrating the MEMS devices for every package. However, it is more desirable to detect defects of the devices by performing an appropriate inspection at an early stage such as in a wafer state after a microfabrication process, thereby raising the production yield after packaging while reducing the manufacturing costs.

As one example of a method for inspecting characteristics of a device having a microstructure, Patent Document 1 discloses an inspecting method for determining characteristics of an acceleration sensor formed on a wafer by detecting a resistance value thereof, which is varied as a result of spraying air to the acceleration sensor.

Patent Document 1: Japanese Patent Laid-open Application No. H5-34371

### DISCLOSURE OF THE INVENTION

### Problems to be Solved by the Invention

When inspecting characteristics of a MEMS device having a microscopic movable section, a physical stimulus needs to be applied to the MEMS device from the exterior. In general, a structure having a microscopic movable section such as an acceleration sensor is a device whose response characteristic varies even for a microscopic movement. Accordingly, a highly accurate inspection is required to be performed to inspect the characteristics of the MEMS device.

As a method for inspecting the acceleration sensor in a wafer state, there is proposed a method of detecting a movement of the movable section by applying a sound wave to the movable section of the sensor. In the method of applying the sound wave to the movable section of the sensor, an opening area is formed in a probe card having probes to be brought into contact with electrodes of the sensor in order to allow a test sound wave to be effectively applied to the microstructure. A probe card surface on the side of the microstructure is configured as a planar surface made of a card forming material.

Since the probe card and the wafer are configured as planar surfaces, an interference of sound waves takes place due to a reverberation between the wafer surface and the probe card surface when outputting the test sound wave to the movable section of the sensor. For this reason, an excessively great input may be required for a sound source in a certain frequency range to obtain a desired sound pressure at a surface of the microstructure. Further, due to the excessively great input, a harmonic wave may be generated, rendering it impossible to carry out a normal test.

In view of the foregoing, the present disclosure provides an inspecting apparatus for determining a characteristic of a microstructure by outputting a sound wave to a movable section thereof, capable of performing a normal dynamic test of the characteristic of the microstructure without having to apply an excessively great input to a sound source.

### Means for Solving the Problems

In accordance with a first aspect of the present invention, there is provided a probe card 4 connected with an evaluation unit 6 for evaluating a characteristic of a microstructure 16 formed on a substrate 8 by outputting a test sound wave to a movable section 16a of the microstructure 16, including: a probe 4a, which is electrically connected with an inspection electrode of the microstructure 16 formed on the substrate 8, for detecting, in a test, an electric variation based on a movement of the movable section 16a formed on the substrate 8; and sound wave adjusting units 11, 17, 18 and 19 for suppressing a reflection or an interference of the test sound wave.

Desirably, the sound wave adjusting units may include a sound absorbing unit 11 provided on a probe card 4's surface facing the substrate 8, for absorbing the test sound wave.

Further, the sound wave adjusting units may include a sound wave diffusing unit 17 provided on a probe card 4's surface facing the substrate 8, for reflecting the test sound wave in a diffusing direction.

Desirably, the sound wave adjusting units may include a blocking unit 18 provided between the probe card 4 and the substrate 8, for restraining the test sound wave from being transmitted from a vicinity of the microstructure 16 to the outside.

Desirably, the sound wave adjusting units may include a sound wave concentrating unit 19 for concentrating the test sound wave to the movable section 16a of the microstructure 16.

In accordance with a second aspect of the present invention, there is provided a microstructure inspecting apparatus 1 including an evaluation unit 6 for evaluating a characteristic of at least one microstructure 16 having a movable section 16a formed on a substrate 8, including: a sound wave generating unit 10 for outputting a test sound wave to the movable section 16a of the microstructure 16; a probe card 4 as claimed in any one of claims 1 to 5; and the evaluation unit 6, connected with the probe card 4, for evaluating the characteristic of the microstructure 16, wherein the evaluation unit 6 detects a movement of the movable section 16a of the microstructure 16 through the probe 4a, the movement being made in response to the test sound wave outputted by the sound wave generating unit 10, and evaluates the characteristic of the microstructure 16 based on the detected result.

### EFFECT OF THE INVENTION

The probe card and the microstructure inspecting apparatus in accordance with the present invention are capable of reproducibly applying a specific sound pressure in a wide frequency range to a microstructure. Accordingly, an excessively great input of electricity need not be applied to a test sound source. Further, since lack of test data in a certain frequency range disappears, reliability of the test data improves.

### BRIEF DESCRIPTION OF THE DRAWINGS

FIG. 1 is a schematic configuration view of a microstructure inspecting apparatus in accordance with an embodiment of the present invention;

FIG. 2 sets forth a block diagram to illustrate a configuration of an inspection control unit and a prober unit of the inspecting apparatus of FIG. 1;

FIG. 3 presents a top view of a triple-axis acceleration sensor;

FIG. 4 is schematic configuration view of the triple-axis acceleration sensor;

FIG. 5 illustrates strains of weight bodies and beams when an acceleration is applied in each axial direction;

FIGS. 6A and 6B are circuit diagrams of Wheatstone bridges installed on each axis;

FIG. 7 illustrates a conceptual configuration view for performing an inspection of a microstructure on a wafer;

FIG. 8 offers a cross sectional view to illustrate a configuration of a probe card in case when an outputted test sound wave is not adjusted;

FIG. 9 presents a schematic view to illustrate a configuration of a probe card in accordance with a first embodiment of the present invention;

FIG. 10 is a graph showing an input voltage applied to a speaker in case when an outputted test sound wave is not adjusted;

FIG. 11 is a graph showing a frequency component of a test sound wave detected by a microphone;

FIG. 12 sets forth a graph showing an example of an input voltage applied to a speaker in the configuration of the first embodiment;

FIG. 13 presents a cross sectional view showing a sound wave diffusing portion provided at a probe card;

FIG. 14 depicts a cross sectional view to illustrate a configuration of a probe card in accordance with a second embodiment of the present invention;

FIG. 15 is a graph showing an example of an input voltage applied to a speaker in the configuration of the second embodiment;

FIG. 16 provides a cross sectional view to illustrate a configuration of a probe card in accordance with a third embodiment of the present invention;

FIG. 17 depicts a graph showing an example of an input voltage applied to a speaker;

FIG. 18 illustrates a graph showing results of Examples 1 to 3;

FIGS. 19A and 19B provide conceptual configuration views to illustrate an example of a pressure sensor; and

FIG. 20 sets forth a flowchart to describe an example operation of the inspecting apparatus in accordance with the embodiment of the present invention.

### EXPLANATION OF CODES

1 Inspecting apparatus
2 Inspection control unit
3 Speaker control unit
4 Probe card
4a Probes
4b Opening area
6 Characteristic evaluation unit (Evaluation unit)
7 Switching unit
8 Wafer (Substrate)
10 Speaker (Sound wave generating unit)
11 Sound absorber (Sound absorbing unit)
13 Probe control unit
15 Prober unit
16 Acceleration sensor (Microstructure)
16a Movable section
17 Diffusion portion (Sound wave diffusing unit)
18 Blocking portion (Blocking unit)
19 Horn (Sound wave concentrating unit)
AR Weight body (Movable section)
BM Beams (Movable sections)

### BEST MODE FOR CARRYING OUT THE INVENTION

Hereinafter, embodiments of the present invention will be described in detail with reference to the accompanying drawings. In the accompanying drawings, like reference numerals designate like parts or corresponding parts.

### First Embodiment

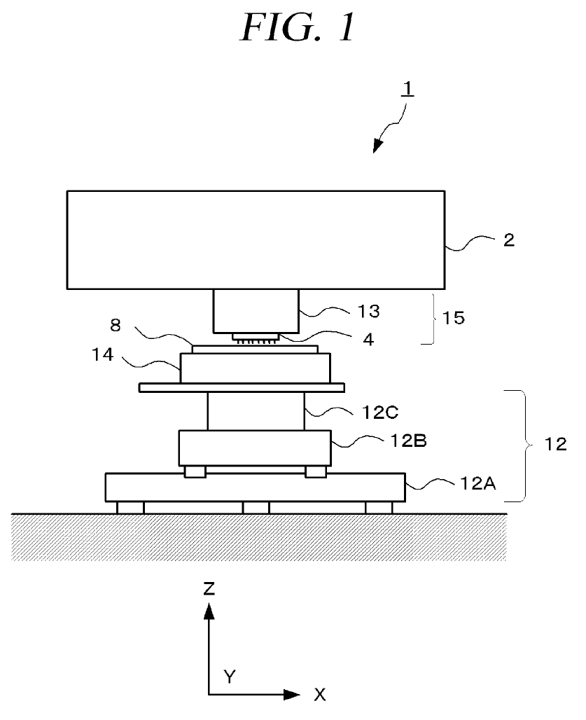

FIG. 1 provides a schematic configuration view of an inspecting apparatus 1 in accordance with an embodiment of the present invention. As shown in FIG. 1, the inspecting apparatus 1 includes a loader unit 12 for transferring a test target object, for example, a wafer 8; a prober unit 15 for performing an inspection of electrical characteristics of the wafer 8; and an inspection control unit 2 for measuring characteristic values of an acceleration sensor, which is provided on the wafer 8, by the prober unit 15.

The loader unit 12 includes a mounting member (not shown) for mounting thereon a cassette accommodating, e.g., twenty five sheets of wafers 8; and a wafer transfer mechanism for transferring the wafers 8 from the cassette of the mounting member sheet-by-sheet.

The wafer transfer mechanism has a main chuck 14 moving along three axial directions (i.e., X-, Y- and Z-axis directions) by X, Y and Z tables 12B, 12A and 12C which function as moving mechanisms in three orthogonal axes of X, Y and Z, respectively. The main chuck 14 is provided to rotate the wafer 8 around the Z axis. To elaborate, the wafer transfer mechanism includes the Y table 12A moving along the Y direction, the X table 12B moving on the Y table 12A along the X direction; and the Z table 12C moving up and down along the Z direction, wherein the Z table 12C is disposed such that its axial center is aligned to be coincident with the center of the X table 12B. The main chuck 14 is moved in the X, Y and Z directions by the X table 12B, the Y table 12A and the Z table 12C, respectively. Further, the main chuck 14 is also rotated in forward and backward directions within a predetermined range by a rotation driving mechanism rotating around the Z axis.

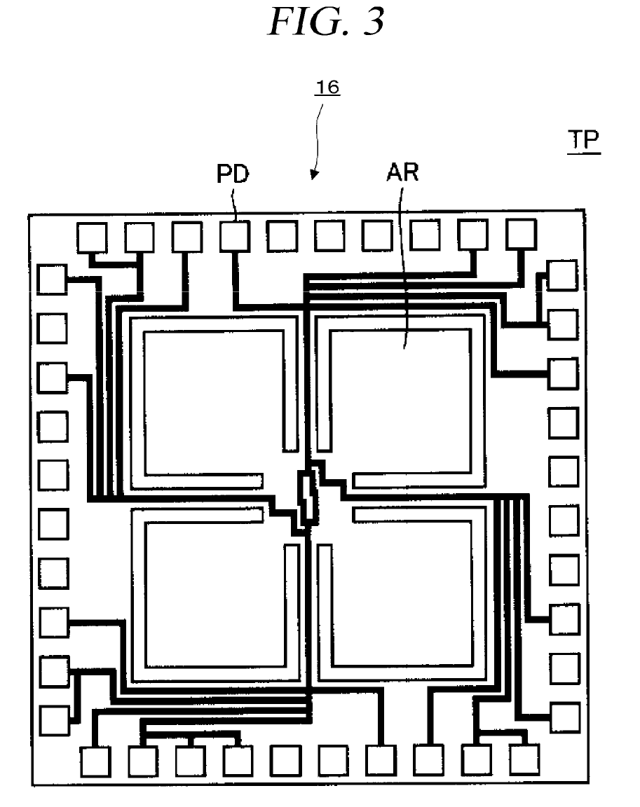

The prober unit 15 includes a probe card 4 and a probe control unit 13 for controlling the probe card 4. The probe card 4 includes testing probes 4a which are brought into contact with electrode pads PD (see FIG. 3) formed on the wafer 8 and made of a conductive metal such as copper, a copper alloy, aluminum or the like. When the probes 4a and the electrode pads PD come into contact with each other, a contact resistance therebetween is reduced by a fritting phenomenon, so that they are allowed to be electrically connected with each other.

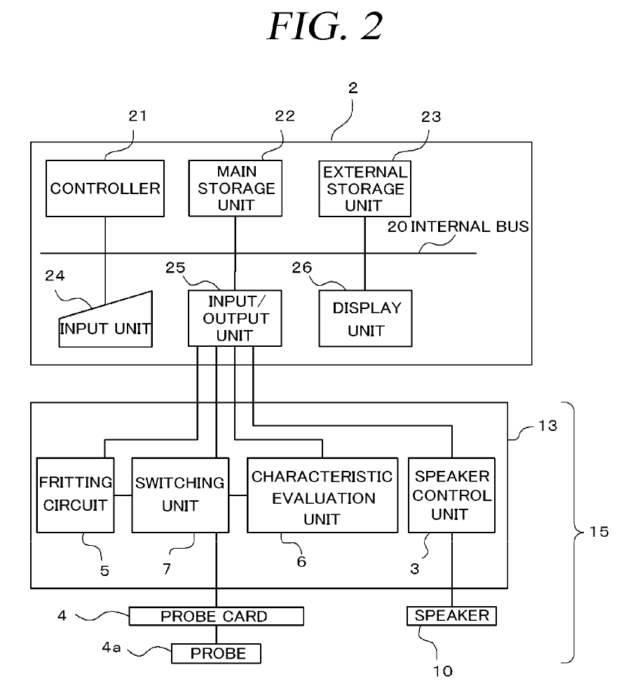

Further, the prober unit 15 includes a speaker 10 (see FIG. 2) for applying a sound wave to a movable section 16a (see FIG. 8) of an acceleration sensor 16 (see FIG. 3) formed on the wafer 8. The probe control unit 13 controls the probes 4a of the probe card 4 and the speaker 10, and applies a certain displacement to the acceleration sensor 16 and then detects a movement of the movable section 16a of the acceleration sensor 16 as an electric signal through the probes 4a.

The prober unit 15 includes an alignment mechanism (not shown) for carrying out alignment of the probes 4a of the probe card 4 to the wafer 8. The prober unit 15 measures characteristic values of the acceleration sensor 16 formed on the wafer 8 by allowing the probes 4a of the probe card 4 and the electrode pads PD on the wafer 8 to come into electrical contact with each other.

FIG. 2 is a block diagram illustrating configurations of the inspection control unit 2 and the prober unit 15 of the inspecting apparatus 1. The inspection control unit 2 and the prober unit 15 constitute an acceleration sensor evaluation and measurement circuit.

As shown in FIG. 2, the inspection control unit 2 includes a controller 21, a main storage unit 22, an external storage unit 23, an input unit 24, an input/output unit 25 and a display unit 26. The main storage unit 22, the external storage unit 23, the input unit 24, the input/output unit 25 and the display unit 26 are all connected to the controller 21 via an internal bus 20.

The controller 21 includes a CPU (Central Processing Unit) or the like, and it performs a process for measuring characteristics of a sensor on the wafer 8, for example, a resistance value of a resistor, a current or a voltage of a circuit constituting the sensor, and the like according to a program stored in the external storage unit 23.

The main storage unit 22 includes a RAM (Random-Access Memory) or the like, and loads therein the program stored in the external storage unit 23 and is used as a working area of the controller 21.

The external storage unit 23 includes a nonvolatile memory such as a ROM (Read Only Memory), a flash memory, a hard disk, a DVD-RAM (Digital Versatile Disc Random-Access Memory), a DVD-RW (Digital Versatile Disc Rewritable), or the like, and pre-stores therein the program required to allow the desired process to be carried out by the controller 21. Further, in response to a command from the controller 21, the external storage unit 23 supplies data stored by the program to the controller 21, and also stores therein data sent from the controller 21.

The input unit 24 includes a keyboard, a pointing device such as a mouse, and an interface device for connecting the keyboard and the pointing device to the internal bus 20. The start of evaluation and measurement, the selection of a measurement method, or the like is inputted through the input unit 24 and is sent to the controller 21.

The input/output unit 25 includes a serial interface or a LAN (Local Area Network) interface connected to the probe control unit 13 which is under the control of the inspection control unit 2. Through the input/output unit 25, instructions upon a contact of the probes 4a with the electrode pads PD of the wafer 8; an electrical conduction therebetween; a switching operation thereof; a control of a frequency and a sound pressure of a test sound wave outputted to the movable section 16a of the acceleration sensor 16; and the like are transmitted to the probe control unit 13. Further, measured results are inputted thereto.

The display unit 26 has a CRT (Cathode Ray Tube), an LCD (Liquid Crystal Display), or the like, and displays thereon, for example, a frequency response characteristic which is a measured result.

The probe control unit 13 includes a speaker control unit 3, a fritting circuit 5, a characteristic evaluator 6 and a switching unit 7. The characteristic evaluator 6 supplies the probe card 4 with a power for measuring an electric signal of the acceleration sensor 16, and measures a current flowing in the acceleration sensor 16, a voltage between terminals, and so forth.

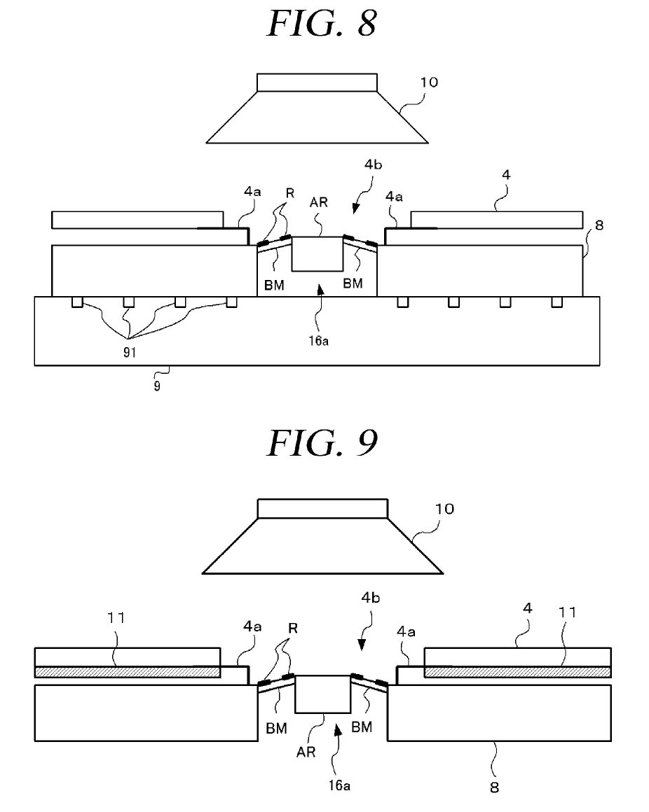

The speaker control unit 3 controls the frequency and the sound pressure of the sound wave emitted from the speaker 10 to make a displacement to the movable section 16a (see FIG. 9) of the acceleration sensor 16 formed on the wafer 8.

The fritting circuit 5 is a circuit which supplies electric currents to the probes 4a of the probe card 4 in contact with the electrode pads PD of the wafer 8, and generates a fritting phenomenon between the probes 4a and the electrode pads PD to thereby reduce the contact resistance therebetween.

The characteristic evaluator 6 measures and evaluates characteristics of a microstructure. For example, the characteristic evaluator 6 applies a static or dynamic displacement to the movable section 16a and then measures a response of the acceleration sensor 16, and determines whether it is within a designed reference range.

The switching unit 7 performs a switching operation to connect each probe 4a of the probe card 4 to either one of the fritting circuit 5 and the characteristic evaluator 6.

Before explaining an inspecting method in accordance with an embodiment of the present invention, a triple-axis acceleration sensor 16 of a microstructure to be inspected will be described first.

FIG. 3 illustrates a top view of the triple-axis acceleration sensor 16. As shown in FIG. 3, a multiplicity of electrode pads PD are disposed on the periphery of a chip TP formed on the wafer 8, and metal interconnections are also provided on the chip TP to transceive electric signals to and from the electrode pads PD. Further, on a central portion of the chip TP, there are arranged four weight bodies AR in a clover shape.

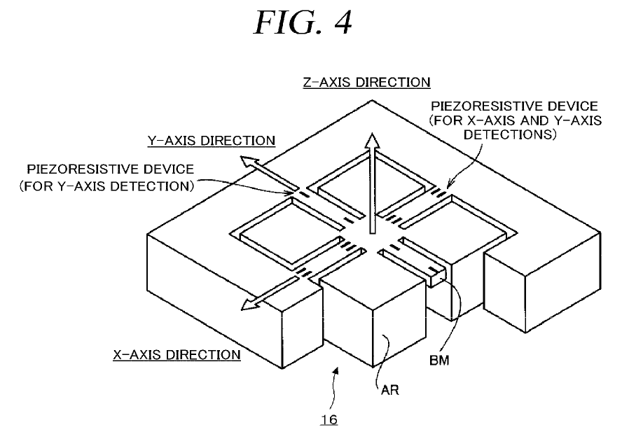

FIG. 4 presents a schematic view of the triple-axis acceleration sensor 16. The triple-axis acceleration sensor 16 is of a piezoresistive type in which piezoresistive devices serving as detecting elements are installed as diffusion resistors. The acceleration sensor 16 of the piezoresistive type can be fabricated through a low-cost IC process. Since the sensitivity of the acceleration sensor does not deteriorate even if the resistor devices, which serve as the detecting elements, are formed small, this type of acceleration sensor is advantageous for device miniaturization and cost reduction.

To elaborate the configuration of the acceleration sensor 16, a central portion of the weight body AR is supported by four beams BM. The beams BM are arranged to cross each other perpendicularly in two axial directions, i.e., X- and Y-axis directions, and four piezoresistive devices are provided along each axis. Further, four piezoresistive devices for Z-axis directional detection are disposed beside the piezoresistive devices for the X-axis directional detection. Top surfaces of the weight body AR form the clover shape, and they are connected to the beams BM at the central portion thereof. By adopting the clover-shaped structure, the size of the weight body AR and the length of the beams can be expanded, so that a compact high-sensitivity acceleration sensor 16 can be realized.

The operation principle of the piezoresistive type triple-axis acceleration sensor 16 is as follows. If a weight body AR is given an acceleration (force of inertia), the beams BM are strained, and the acceleration is detected based on a variation in resistance values of the piezoresistive devices formed on the surfaces of the beams BM. Sensor outputs are obtained from outputs of Wheatstone bridges independently disposed on each of the three axes.

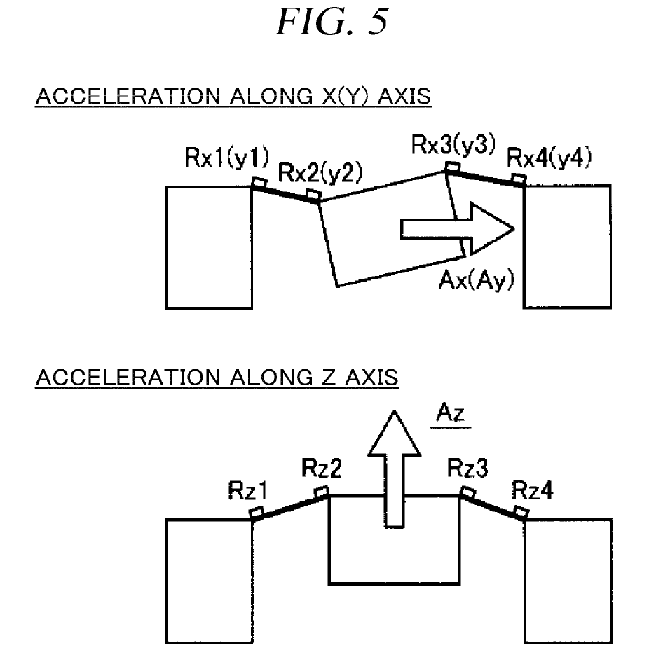

FIG. 5 presents a conceptual diagram to describe strain of the weight body and the beams when the acceleration is applied in each axial direction. As illustrated in FIG. 5, a piezoresistive device is characterized in that its resistance value is varied by a strain applied thereto (referred to as a piezoresistive effect). In case of an extension strain, the resistance value increases, while the resistance value decreases in case of a compression strain. In the present embodiment, X-axis directional detection piezoresistive devices (Rₓ1 to Rₓ4), Y-axis directional detection piezoresistive devices (R_{y}1 to R_{y}4) and Z-axis directional detection piezoresistive devices (R_{z}1 to R_{z}4) are provided for illustration.

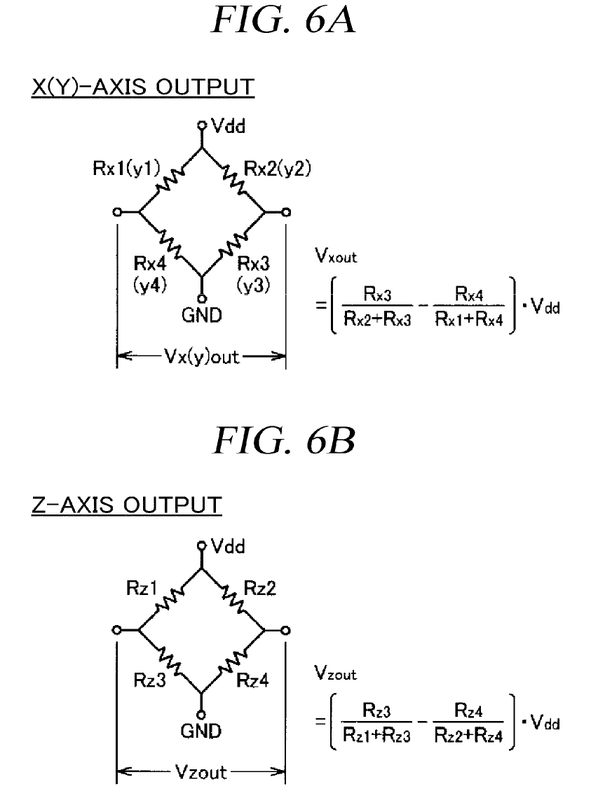

FIGS. 6A and 6B show circuit diagrams of Wheatstone bridges provided on the respective axes. FIG. 6A is a circuit diagram of the Wheatstone bridge on the X (Y) axis, while FIG. 6B is a circuit diagram of the Wheatstone bridge on the Z axis. Output voltages of the X and Y axes are set to be Vₓₒᵤₜ and V_{yout}, respectively, and an output voltage of the Z axis is set to be V_{zout}.

As described above, due to the inflicted strain, the resistance values of the four piezoresistive devices on each axis are varied. Based on these variations of each piezoresistive device, circuit outputs generated by the Wheatstone bridges on, for example, the X and Y axes, that is, acceleration components of the X and Y axes are detected as independently separated output voltages. Further, as the configuration of the above circuit, metal interconnections as shown in FIG. 3 or the like are connected, so that the output voltage for each axis is detected from the electrode pad PD.

Referring again to FIGS. 1 and 2, the microstructure inspecting method in accordance with the embodiment of the present invention is a method in which a test sound wave generated from the speaker 10 is applied to the triple-axis acceleration sensor 16, i.e., the microstructure, so that characteristics of the microstructure are evaluated by detecting movements of the movable section 16a of the microstructure based on the test sound wave.

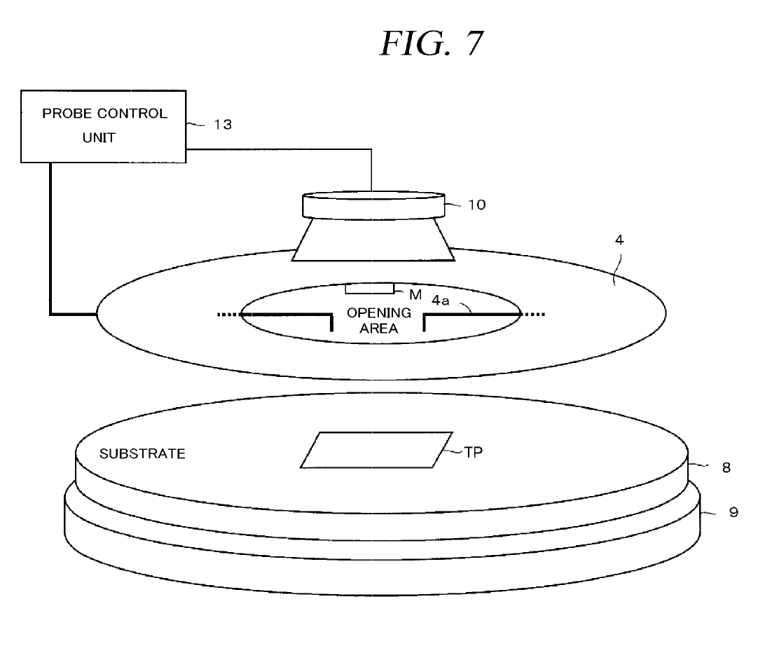

Now, an evaluation method for the acceleration sensor 16 in accordance with the embodiment of the present invention will be explained. FIG. 7 illustrates a conceptual configuration view for performing an inspection of the microstructure on the wafer 8. The probe card 4 includes the speaker 10 which serves as a test sound wave outputting unit. The probe card 4 is provided with an opening area at a position corresponding to the test sound wave outputting unit, so that the sound wave from the speaker 10 is allowed to reach a chip TP to be inspected through the opening area. The probes 4a are installed at the probe card 4 to protrude toward the opening area. Further, a microphone M is installed near the opening area. By detecting a sound wave around the chip TP by the microphone M, the test sound wave outputted from the speaker 10 is controlled so that the sound wave applied to the chip TP has a desired frequency component.

The speaker control unit 3 outputs the test sound wave in response to a test instruction assigned to the prober unit 15. As a result, for example, the movable section 16a of the triple-axis acceleration sensor 16 is moved, so that it becomes possible to detect an electric signal according to the movement of the movable section 16a from an inspection electrode via the probe 4a which is electrically connected with the inspection electrode by a fritting phenomenon. It is also possible to perform a device inspection by measuring and analyzing this signal by the probe control unit 13.

FIG. 8 is a cross sectional view showing a configuration of the probe card 4 when an adjustment of the test sound wave outputted from the speaker 10 is not performed. Though a plurality of acceleration sensors 16 are actually provided on the wafer 8, only one acceleration sensor 16 is shown in FIG. 8 for the simplicity of explanation. FIG. 8 illustrates a state in which the movable section 16a of the acceleration sensor is displaced upward.

The wafer 8 is mounted on a chuck top 9 of a vacuum chuck. The vacuum chuck has vacuum grooves 91 provided in a top surface of the chuck top 9. The vacuum grooves 91 are connected with a vacuum chamber (not shown) by a conducting pipe passing though the inside of the chuck top 9 so that a gas therein is sucked, and the wafer 8 is attracted and held on the chuck top 9 by a negative pressure of the vacuum grooves 91.

As described above, the acceleration sensor 16 of the wafer 8 includes the movable section 16a which has a structure in which both sides of the weight body AR are supported by the beams BM. The piezoresistive devices R are installed on the beams BM, and each piezoresistive device R outputs a signal according to a distortion due to a strain of each beam BM. The probe 4a is brought into contact with the electrode of the acceleration sensor 16, and the acceleration sensor 16 outputs the signal of the piezoresistive device R to the outside. The speaker 10 is disposed above the probe card 4 to apply the test sound wave to the movable section 16a.

The test sound wave outputted from the speaker 10 is introduced between the probe card 4 and the wafer 8 through the opening area 4b of the probe card 4 and is reflected to go back to the movable section 16a. Further, the test sound wave is also introduced between the probe card 4 and the wafer 8 from the outside of the probe card 4 to reach the movable section 16a. A direct wave of the test sound wave outputted from the speaker 10, a test sound wave reflected between the probe card 4 and the wafer 8, and a test sound wave introduced from the outside of the probe card 4 interfere with each other on the movable section 16a. As a result, the test sound wave may be weakened at a certain frequency at a location on the movable section 16a.

Further, the inspecting apparatus 1 may have a configuration in which the speaker 10 is enclosed with a cylindrical member connected to a periphery of the probe card 4 so that the introduction of the test sound wave between the probe card 4 and the wafer 8 from the outside of the probe card 4 can be suppressed.

The speaker control unit 3 detects the test sound wave near the movable section 16a by the microphone M, and controls an output of the speaker 10 such that the test sound wave has a preset frequency and sound pressure. If the sound pressure of the test sound wave of a certain frequency is weakened due to the interference of a reflection wave or a diffraction wave, the speaker control unit 3 increases an input voltage to the speaker 10 such that the sound pressure of the test sound wave reaches the preset sound pressure level. As a result, the input voltage of the speaker 10 increases at a frequency where attenuation occurs due to the interference. Sometimes, the input voltage may become excessively great, resulting in a generation of a harmonic wave. Further, if the input voltage is increased, noise components also increase, thereby causing a deterioration of an S/N ratio along with the harmonic wave distortion.

FIG. 9 is a cross sectional view illustrating a configuration of the probe card 4 in accordance with a first embodiment of the present invention, wherein an illustration of the chuck top 9 is omitted in this figure. A sound absorber 11 is provided on a probe card 4's surface corresponding to the wafer 8. The sound absorber 11 has elasticity and is made of a material having a high internal loss, e.g., a foamed polymer material. Desirably, the sound absorber 11 is made of a material having a high sound wave absorbing rate through a wide frequency band, e.g., a sponge.

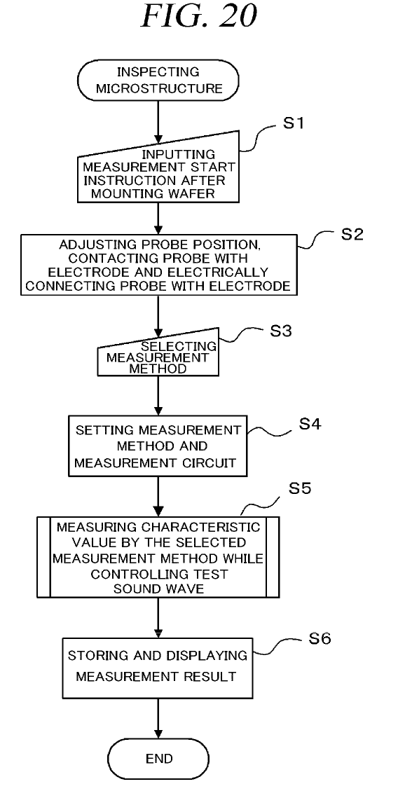

Now, the inspecting method for inspecting the microstructure in accordance with the first embodiment of the present invention will be described. FIG. 20 provides a flowchart to describe an example operation of the inspecting apparatus in accordance with the embodiment of the present invention. The operation of the inspection control unit 2 is performed by the controller 21 working in cooperation with the main storage unit 22, the external storage unit 23, the input unit 24, the input/output unit 25 and the display unit 26.

The inspection control unit 2 first waits for a measurement start instruction to be inputted after the wafer 8 is loaded on the main chuck 14 (step S1). When the measurement start instruction is inputted to the controller 21 from the input unit 24, the controller 21 sends an instruction to the probe control unit 13 via the input/output unit 25 to allow the probes 4a to come into contact with the electrode pads PD of the wafer 8 (step S2). Subsequently, an instruction is sent to the probe control unit 13 to connect the probes 4a with the electrode pads PD electrically by the fritting circuit 5 (step S2).

In the present embodiment, though the contact resistance between the electrode pads PD and the probes 4a is reduced by the fritting phenomenon, other techniques besides the fritting technology can also be employed as a method for allowing the electric conduction by reducing the contact resistance. For example, there can be employed a method of reducing the contact resistance between the electrodes pads PD and the probes 4a by transmitting ultrasonic waves to the probes 4a to partially destroy oxide films on surfaces of the electrode pads PD.

Thereafter, a selection of a measurement method is inputted (step S3). The measurement method may be stored in the external storage unit 23 in advance, or may be inputted from the input unit 24 for every measurement. When the measurement method is inputted, a measurement circuit used by the inputted measurement method, and a frequency and a sound pressure of a test sound wave to be applied to the movable section 16a are set (step S4).

The measurement methods to be selected include, for example, a frequency sweeping inspection (frequency scan) for inspecting a response at each frequency by successively varying the frequency of the sound wave, a white noise inspection for inspecting a response by applying a pseudo white noise within a preset frequency range, a linearity inspection for inspecting a response by varying a sound pressure of the sound wave while fixing the frequency of the sound wave at a certain value, and so forth.

Then, by employing the selected measurement method, an electric signal, i.e., a response of the acceleration sensor 16 is detected from the probes 4a while displacing the movable section 16a of the acceleration sensor 16 by controlling the speaker control unit 3, so that a response characteristic of the acceleration sensor 16 is inspected (step S5). Then, a detected measurement result is stored in the external storage unit 23 and displayed on the display unit 26 (step S6).

In the above-described first embodiment, the response characteristic of the acceleration sensor 16 is inspected while outputting the test sound wave to the movable section 16a of the acceleration sensor 16 from the speaker 10. At this time, the test sound wave introduced between the probe card 4 and the wafer 8 is absorbed by the sound absorber 11, so that a reflection wave and a diffraction wave toward the movable section 16a are reduced. Accordingly, an interference of the test sound wave at the movable section 16a decreases. As a result, it is possible to reduce the input voltage to the speaker 10 at a frequency where the interference takes place, and, at the same time, a generation of a harmonic wave can be suppressed. The reduction of the input voltage in turn allows a decrease of noise components, and the suppression of the harmonic waves together with an improvement of the S/N ratio. Further, a loss of test data in a certain frequency range does not occur, so that reliability of the test data improves. Moreover, since an excessively great electric input to the speaker 10 is not necessary, lifetime of the inspecting apparatus 1 can be increased.

### Example 1

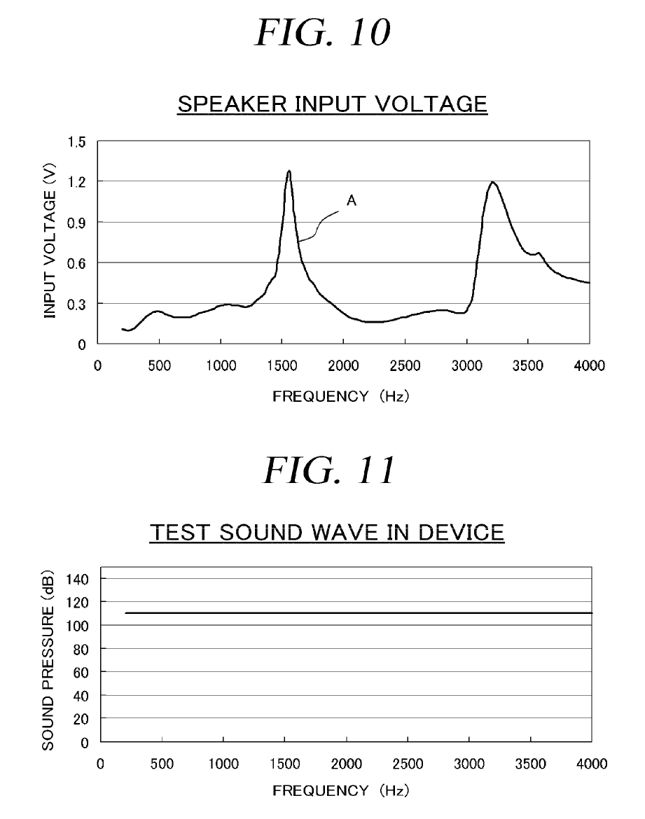

FIG. 10 is a graph showing an input voltage applied to the speaker 10 in case without performing an adjustment of the test sound wave outputted from the speaker 10 (i.e., in case of FIG. 8). FIG. 11 sets forth a graph showing a frequency component of the sound test wave detected by the microphone M. FIG. 10 shows the result of controlling the input voltage of the speaker 10 so that the sound pressure of the test sound wave in the vicinity of the movable section 16a is maintained constant over the entire inspected frequency range, as illustrated in FIG. 11. A vertical axis of the graph in FIG. 10 represents an input voltage applied to the speaker 10, while a horizontal axis thereof represents a frequency of the test sound wave.

The input voltage of the speaker 10 was controlled so that the sound pressure of the test sound wave detected by the microphone M became about 110 dB at each frequency, as shown in FIG. 11. As can be seen from the input voltage A in FIG. 10, remarkable peaks are found to exist near frequencies of about 1580 Hz and about 3240 Hz. Since the test sound wave is attenuated due to interference at frequencies near the peaks, the input voltage is increased to compensate for it.

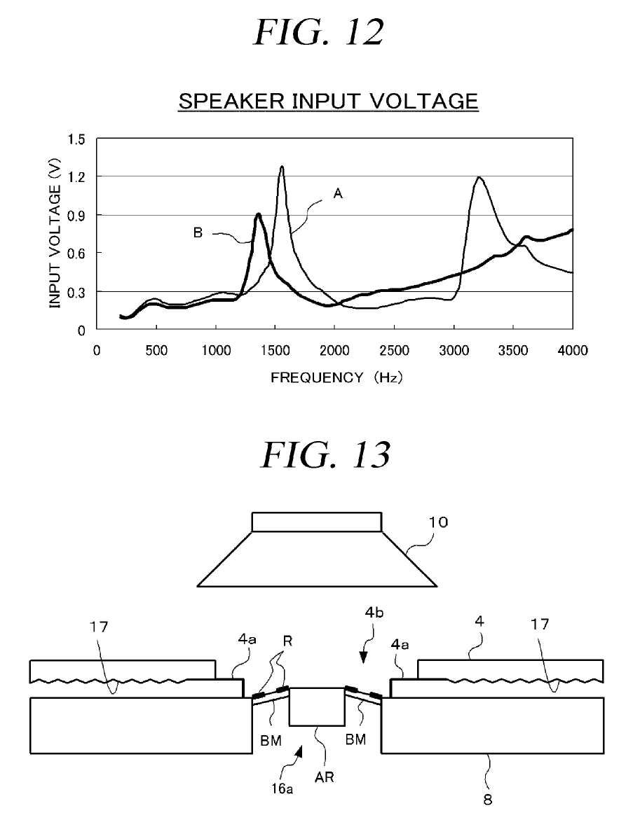

FIG. 12 presents a graph showing an input voltage B applied to the speaker 10 in the configuration shown in FIG. 9 in accordance with the first embodiment. For comparison, FIG. 12 also provides the input voltage A to the speaker 10 in case without performing the adjustment of the outputted test sound wave. In this case, the input voltage of the speaker 10 was also controlled such that the sound pressure of the test sound wave detected by the microphone M was maintained at about 110 dB.

The reflection wave and the diffraction wave between the probe card 4 and the wafer 8 are attenuated by the sound absorber 11. As a result, the interference of the test sound wave at the movable section 16a is also reduced, so that a peak of the input voltage B is reduced. Especially, a peak around a frequency of about 3240 Hz disappears. The input voltage B is almost less then about 0.9 V across the entire frequency range, and there is found no frequency where an input voltage is excessively great (for example, about 1.0 V or higher).

Though the input voltage B is larger than the input voltage A at some frequencies, the test sound wave is deemed to get stronger in those frequency ranges due to the interference. However, it is conjectured that when there is no sound absorber 11 (input voltage A), a deformation of waveform of the test sound wave or a generation of a harmonic wave would occur in those frequency ranges due to the interference.

### Modification of the First Embodiment

FIG. 13 is a cross sectional view showing a configuration in which a diffusing portion for a sound wave is provided at the probe card 4. A diffusing portion 17 having prominences and depressions is formed at a probe card 4's surface facing the wafer 8 to diffuse a sound wave. The probe card 4's surface facing the wafer 8 may be formed in a shape having the prominences and depressions, or may be formed by attaching a member having the prominences and depressions. It is desirable to form the diffusing portion 17 in a shape with irregular prominences and depressions to diffuse the sound wave in all directions.

Since a reflection wave and a diffraction wave between the probe card 4 and the wafer 8 are diffused by the diffusing portion 17 and reflected, an interference of the test sound wave at a certain place, e.g., at the movable section 16a, would be reduced. As a result, an effect similar to that obtained by the formation of the sound absorber 11 (FIG. 9) can be acquired. It is more effective to form prominences and depressions in the surface of the sound absorber 11 by combining the sound absorber 11 and the diffusing portion 17.

### Second Embodiment

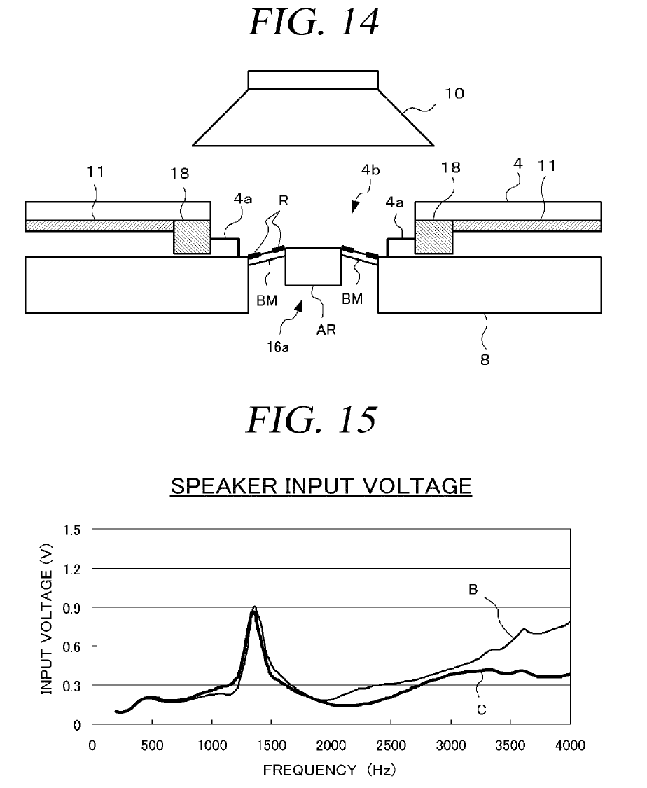

FIG. 14 is a cross sectional view showing a configuration of a probe card 4 in accordance with a second embodiment of the present invention. In this second embodiment, in addition to a sound absorber 11, a blocking portion 18 for blocking a test sound wave is formed at a peripheral portion of an opening area of the probe card 4 to face the wafer 8. The blocking portion 18 is made of a material hardly transmitting a sound wave and is desirably formed to have a certain degree of strength and mass or width.

The blocking portion 18 suppresses an introduction of a test sound wave between the probe card 4 and the wafer 8 from the opening area 4b. Further, the blocking portion 18 also restrains a test sound wave, introduced between the probe card 4 and the wafer 8 from the outside of the probe card 4, from propagating to a movable section 16a.

The blocking portion 18 also serves as a post (a fixing pedestal) of probes 4a. By configuring the blocking portion 18 as the post of the probes 4a, fulcrums of the probes 4a can be located in the vicinity of the wafer 8 even in case that the sound absorber 11 is installed on a probe card 4's side facing the wafer 8. Though the probes 4a are made of a material having a high compliance (i.e., a highly flexible material), the post portion (blocking portion 18) is hardly deformed. Since the fulcrums of the cantilever structures of the probes 4a are located closer to the substrate by the presence of the post portion (blocking portion 18), a displacement direction of tips of the probes 4a becomes substantially perpendicular to the wafer 8. Accordingly, the probes 4a and the wafer 8 are brought into contact with each other by moving the wafer 8 with respect to the probe card 4 in a perpendicular direction to the substrate surface. In such case, even when the tips of the probes 4a are overdriven to obtain a preset probe pressure after the probes 4a and the wafer 8 come into contact with each other, only a stress in a vertical direction is applied to the surface of the wafer 8. Thus, a test of the microstructure can be carried out in a state where a stress in a substrate surface direction is not generated with respect to the microstructure.

In addition to the effect of the sound absorber 11, since the reflection wave and the diffraction wave are suppressed by the blocking portion 18, an interference of the test sound wave at the movable section 16a can be further reduced. As a result, it is possible to reduce an input voltage 10 applied to the speaker 10 at a frequency where the interference takes place, and, at the same time, a generation of a harmonic wave can be suppressed. The reduction of the input voltage in turn allows a decrease of noise components, and the suppression of the harmonic waves together with an improvement of the S/N ratio. Further, a loss of test data in a certain frequency range does not occur, so that reliability of the test data improves. Moreover, since an excessively great electric input to the speaker 10 becomes unnecessary, lifetime of the inspecting apparatus 1 can be increased.

### Example 2

FIG. 15 is a graph showing an input voltage C applied to the speaker 10 in the configuration in accordance with the second embodiment shown in FIG. 14. For comparison, FIG. 15 also shows the input voltage B to the speaker 10 in the configuration in accordance with the first embodiment. The input voltage of the speaker 10 was controlled such that a sound pressure of a test sound wave detected by the microphone M reached 110 dB at each frequency.

In comparison with the first embodiment, the input voltage is further reduced by the blocking portion 18. Especially, the input voltage C is smaller than the input voltage B in a frequency range greater than or equal to about 2000 Hz. That is, it is deemed to imply that the blocking portion 18 suppresses frequency components of the reflection wave and the diffraction wave which are not completely attenuated by the sound absorber 11. Moreover, it is also deemed that the degree of concentration of the test sound wave to the movable section 16a is enhanced by the blocking portion 18.

### Third Embodiment

FIG. 17 is a cross sectional view showing a configuration of a probe card 4 in accordance with a third embodiment of the present invention. In the third embodiment, in addition to a sound absorber 11 and a blocking portion 18, a horn 19 is formed along a surface connecting an opening periphery of a speaker 10 and an opening area periphery of the probe card 4 between the speaker 10 and the probe card 4. The horn 19 is made of a material hardly transmitting a sound wave, and is desirably formed to have a certain degree of strength and mass and width. Further, when an opening of the speaker 10 is larger than an opening area 4b of the probe card 4, the horn 19 may be formed in a truncated cone shape along the surface connecting the opening periphery of the speaker 10 and the opening area periphery of the probe card 4.

The horn 19 suppresses a propagation of the test sound wave to a place other than the opening area 4b of the probe area 4b, thereby allowing the test sound wave to be concentrated to the movable section 16a through the opening area 4b of the probe card 4. Further, the horn 19 also suppresses an introduction of the sound test wave between the probe card 4 and the wafer 8 from the outside of the probe card 4.

Since the test sound wave is concentrated to the movable section 16a by the horn 19 while prevented from propagating to regions other than the movable section 16a, a reflection wave and a diffraction wave of the test sound wave are reduced, so that the interference of the test sound wave at the movable section 16a is further reduced. As a result, by using the horn 19, the inspecting apparatus 1 can lower an input voltage to be applied to the speaker 10 at a frequency where the interference takes place. At the same time, it is also possible to suppress a generation of a harmonic wave. The reduction of the input voltage in turn allows a reduction of the noise components, and the suppression of the harmonic waves together with an improvement of an S/N ratio. Furthermore, a loss of test data at a certain frequency range disappears, so that reliability of test data can be improved. Moreover, an excessively great electric input to the speaker 10 becomes needless, so that lifetime of the inspecting apparatus 1 increases.

### Example 3

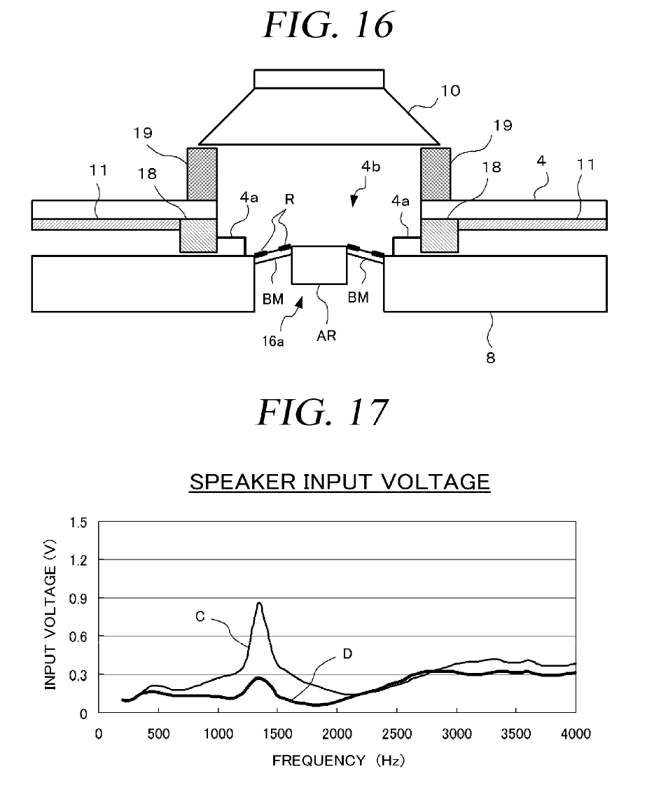

FIG. 17 is a graph showing an input voltage D applied to the speaker 10 in the configuration in accordance with the third embodiment illustrated in FIG. 16. For comparison, FIG. 17 also shows the input voltage C to the speaker 10 in case of the second embodiment. The input voltage of the speaker 10 was controlled such that a sound pressure of a test sound wave detected by the microphone M reached 110 dB at each frequency.

In comparison with the second embodiment, the input voltage is reduced in a wider range of frequency bands. Especially, though a peak of about 0.85 V remains at the frequency of about 1350 Hz or thereabout in the input voltage C, the peak is greatly reduced to about 0.3 V or less in the input voltage D. That is, the horn 19 is proved to have an effect of concentrating the test sound wave.

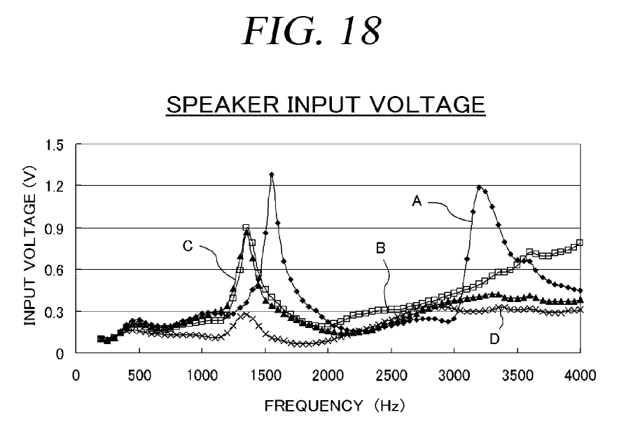

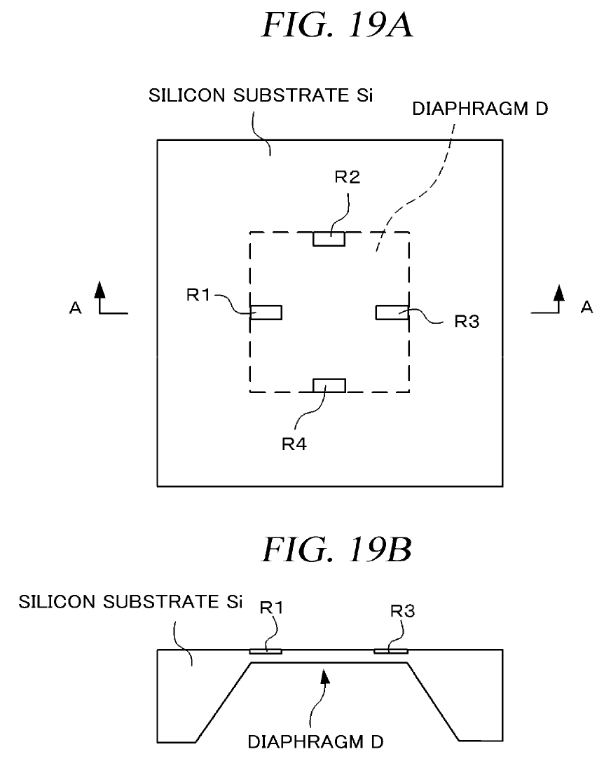

FIG. 18 is a graph showing the results of the Examples 1 to 3 altogether. FIG. 19 shows, in the single graph, the input voltage A in case without performing the adjustment of the outputted test sound wave; the input voltage B in case of installing the sound absorber 11 at the probe card 4; the input voltage C in case of adding the blocking portion 18 to the sound absorber 11; and the input voltage D in case of installing the horn 19 in addition to the sound absorber 11 and the blocking portion 18. In each case, the input voltage of the speaker 10 was controlled such that a sound pressure of a test sound wave detected by the microphone M became about 110 dB at each frequency.

As can be seen from FIG. 18, the input voltage to the speaker 10 for obtaining the same sound pressure decreases as the input voltage A changes to the input voltage D. From this result, it is proved that each of the sound absorber 11, the blocking portion 18 and the horn 19 has an effect of reducing the interference of the test sound wave. Especially, they have an effect of reducing a peak voltage of the speaker input.

Though the above embodiments have been described with respect to the acceleration sensor 16, the inspecting apparatus 1 of the present invention can be applied to various types of devices having a movable section which can be moved by a test sound wave. For example, the present invention can be applied to a film-structured movable section of a pressure sensor and the like. FIGS. 19A and 19B provide schematic conceptual configuration views to describe an example pressure sensor. FIG. 19A is a plan view of the pressure sensor, and FIG. 19B is a cross sectional view taken along a line A-A of FIG. 19A.

As illustrated in FIGS. 19A and 19B, a substantially square diaphragm D having a thin thickness is installed in a central portion of a silicon substrate Si. Piezoresistive devices R1 to R4 are provided at the center of four sides of the diaphragm D, respectively. If the diaphragm D is strained due to a pressure difference between both surfaces of the diaphragm D, stresses are generated to the piezoresistive devices R1 to R4. Since electric resistance values of the piezoresistive devices R1 to F4 are varied due to the stresses, it is possible to measure the pressure difference between both surfaces of the diaphragm D by detecting the variation.

As for the pressure sensor, it is possible to inspect characteristics of the microstructure by detecting the variation while outputting the test sound wave to the diaphragm D by using the inspecting apparatus 1. In such case, by using the probe cards 4 disclosed in the first to the third embodiments, the input voltage applied to the speaker 10 can be reduced. At the same time, it is also possible to suppress a generation of a harmonic wave. The reduction of the input voltage in turn allows a reduction of the noise components, and the suppression of the harmonic waves together with an improvement of an S/N ratio. Furthermore, a loss of test data at a certain frequency range disappears, so that reliability of test data can be improved. Moreover, since an excessively great electric input to the speaker 10 becomes needless, the lifetime of the inspecting apparatus 1 can be increased.

Besides, it should be noted that the above-described hardware configurations or the flowcharts are nothing more than examples, so that they can be changed or modified in various ways. Further, it is also possible to use the sound absorber 11, the diffusing portion 17, the blocking portion 18 and the horn 19 in any combinations.

The present application claims the benefit of Japanese Patent Application Ser. No. 2006-268431, filed on Sep. 29, 2006, of which specification, claims and drawings are hereby incorporated by reference in its entirety.

### INDUSTRIAL APPLICABILITY

The probe card and the microstructure inspecting apparatus have advantages when they are applied to the inspection of characteristics of a device having a microscopic movable section such as MEMS, which is a device integrating a mechanical component, a sensor, an actuator and an electronic circuit on a single silicon substrate.

What is claimed is:

1. A probe card 4 connected with an evaluation unit 6 for evaluating a characteristic of a microstructure 16 formed on a substrate 8 by outputting a test sound wave to a movable section 16a of the microstructure 16, comprising:
a probe 4a, which is electrically connected with an inspection electrode of the microstructure 16 formed on the substrate 8, for detecting, in a test, an electric variation based on a movement of the movable section 16a formed on the substrate 8; and
sound wave adjusting units 11, 17, 18 and 19 for suppressing a reflection or an interference of the test sound wave.

2. The probe card 4 of claim 1, wherein the sound wave adjusting units include a sound absorbing unit 11 provided on a probe card 4's surface facing the substrate 8, for absorbing the test sound wave.

3. The probe card 4 of claim 1, wherein the sound wave adjusting units include a sound wave diffusing unit 17 provided on a probe card 4's surface facing the substrate 8, for reflecting the test sound wave in a diffusing direction.

4. The probe card 4 of claim 1, wherein the sound wave adjusting units include a blocking unit 18 provided between the probe card 4 and the substrate 8, for restraining the test sound wave from being transmitted from a vicinity of the microstructure 16 to the outside.

5. The probe card 4 of claim 1, wherein the sound wave adjusting units include a sound wave concentrating unit 19 for concentrating the test sound wave to the movable section 16a of the microstructure 16.

6. A microstructure inspecting apparatus 1 including an evaluation unit 6 for evaluating a characteristic of at least one microstructure 16 having a movable section 16a formed on a substrate 8, comprising:
a sound wave generating unit 10 for outputting a test sound wave to the movable section 16a of the microstructure 16;
a probe card 4 as claimed in claim 1; and
the evaluation unit 6, connected with the probe card 4, for evaluating the characteristic of the microstructure 16,
wherein the evaluation unit 6 detects a movement of the movable section 16a of the microstructure 16 through the probe 4a, the movement being made in response to the test sound wave outputted by the sound wave generating unit 10, and evaluates the characteristic of the microstructure 16 based on the detected result.
